(19) United States
(12) Patent Application Publication
(10) Pub. No.: US 2013/0048360 A1
(43) Pub. Date: Feb. 28, 2013

(54) SYSTEM IN PACKAGE, PRINTED CIRCUIT BOARD PROVIDED WITH SUCH SYSTEM IN PACKAGE

(71) Applicant: Stijn Vandebril, Kessel-Lo (BE)

(72) Inventor: Stijn Vandebril, Kessel-Lo (BE)

(73) Assignee: OPTION, Leuven (BE)

(21) Appl. No.: 13/497,881

(22) PCT Filed: Sep. 24, 2010
(86) PCT No.: PCT/EP10/64200

§ 371 Date: Nov. 12, 2012

(30) Foreign Application Priority Data
Sep. 24, 2009 (EP) 09171261.2

(51) Int. Cl. B23K 1/20; H05K 1/11

(52) U.S. Cl. 174/260; 228/165

(57) ABSTRACT

Method for providing a printed circuit board (16) with an electronic device (1), wherein the electronic device (1) having at least one external soldering pad (11) having a predetermined size for heat dissipation is soldered with the soldering pad (11) onto a printed circuit board substrate of the printed circuit board (16) such that the electronic device (1) is electrically connected to an electrical circuit provided on the printed circuit board substrate, wherein prior to soldering, one or more through holes (12) are provided in the printed circuit board in the area where the soldering pad (12) is to be soldered to the printed circuit board (16) such that the through hole is provided for allowing flux gasses resulting during soldering of the electronic device (1) to the printed circuit board to escape.

### TECHNICAL FIELD

The present invention relates to a method for providing a printed circuit board with an electronic device, according to the preamble of the first claim.

The invention also relates to a printed circuit board provided with an electronic device according to such method, comprising a printed circuit board substrate on which an electric circuit is provided, the electronic device being electrically connected to the electric circuit, an external soldering pad of the electronic device having a predetermined size for heat dissipation being soldered to the printed circuit board, the printed circuit board comprising one or more through holes extending through the printed circuit board.

### BACKGROUND ART

Such methods for providing a printed circuit board with an electronic device are already known to the person skilled in the art.

In such methods the electronic device has at least one external soldering pad. The soldering pad has a predetermined size for heat dissipation and is soldered with the soldering pad onto a printed circuit board substrate of the printed circuit board such that the electronic device is electrically connected to an electrical circuit provided on the printed circuit board substrate.

However, when soldering the soldering pad of the electronic device to the printed circuit board substrate, there is a substantial risk that flux gasses resulting during soldering of the electronic device to the printed circuit board reduce the quality of the connection of the electronic device with the printed circuit board as for example described in US 2002/0084312 A1.

### DISCLOSURE OF THE INVENTION

Therefore, it is an object of the current invention to provide a method for providing a printed circuit board with an electronic device in which the risk for a poorly connected electronic device is reduced.

This is achieved in the method of the present invention with the technical features of the characterising part of the first claim.

Thereto, prior to soldering, one or more through holes are provided in the printed circuit board in the area where the soldering pad is to be soldered to the printed circuit board such that the through hole is provided for allowing flux gasses resulting during soldering of the electronic device to the printed circuit board to escape.

Provision of such a through-hole has been found to allow a better connection of the electronic device to the printed circuit board as flux gasses resulting from soldering the external soldering pad to the printed circuit board can escape such that they no longer hinder the formation of a connection between the external soldering pad, for example by forming voids as described in US 2002/0084312, and the printed circuit board.

Moreover it has been found that soldering material, especially soldering paste, will spread better over the soldering pads of the electronic device such that the electronic device will collapse more to the printed circuit board leading to a decreased thickness of the overall printed circuit board.

Preferably, the through hole through the printed circuit board is made by making a through hole only through the circuit board substrate aside the electric circuit. Providing a through hole in such a way allows to avoid any unwanted influence on the electric circuit by making the through hole. In such case the through-hole is different from a so-called via possibly present in the printed circuit board but which are part of the electric circuit, the location of which is often determined by the electric circuit and not by the area in which the soldering pad is to be soldered.

According to preferred embodiments of the method for providing a printed circuit board with an electronic device according to the current invention, the rise of temperature within a soak zone during soldering is kept within a range of 7° C./min-15° C./min, more preferably 10° C./min.

The invention also relates to a printed circuit board provided with an electronic device according to the above-described method.

Such a printed circuit board comprises a printed circuit board substrate on which an electric circuit is provided, the electric circuit being electrically connected to the electronic device. The printed circuit board is soldered to an external soldering pad of the electronic device having a predetermined size for heat dissipation. The printed circuit board comprises one or more through holes extending through the printed circuit board. The through hole is provided for allowing flux gasses resulting during soldering of the electronic device to the printed circuit board to escape.

Preferably, the soldering connecting the soldering pad of the electronic device covers the through hole as in such a printed circuit board, an improved connection of the electronic device to the printed circuit board is obtained.

In preferred embodiments of the printed circuit board according to the invention, the through-hole is provided at the centre of the soldering pad. Such a more symmetric positioning further increases the escape of flux gasses resulting from soldering, leading to a further improved attachment of the electronic device to the printed circuit board.

### BRIEF DESCRIPTION OF THE DRAWINGS

The invention will be further elucidated by means of the following description and the appended drawings.

FIG. 1 shows a cross-section of a system in package.

FIG. 2 shows the cross-section according to FIG. 1 after removal of a removable part of the first layer.

FIG. 3 shows a detail of a bottom view of the system in package of FIG. 1.

FIG. 4 shows the bottom view according to FIG. 3 with the removable part removed from the system in package.

FIG. 5 shows a top view of a printed circuit board with indications for the desired location of the system in package shown in FIGS. 2 and 3.

FIG. 6 shows a top view of a pattern for applying solder paste onto the printed circuit board shown in FIG. 5.

FIG. 7 shows a top view of a different pattern for applying solder paste onto a printed circuit board.

FIG. 8 shows a recommended reflow profile for soldering an electronic device to a printed circuit board as shown in FIG. 5.

FIG. 9 shows a side view of a printed circuit board provided with an electronic device and SMD which was used to obtain the data of FIG. 8.

### MODES FOR CARRYING OUT THE INVENTION

The present invention will be described with respect to particular embodiments and with reference to certain drawings but the invention is not limited thereto but only by the claims. The drawings described are only schematic and are non-limiting.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

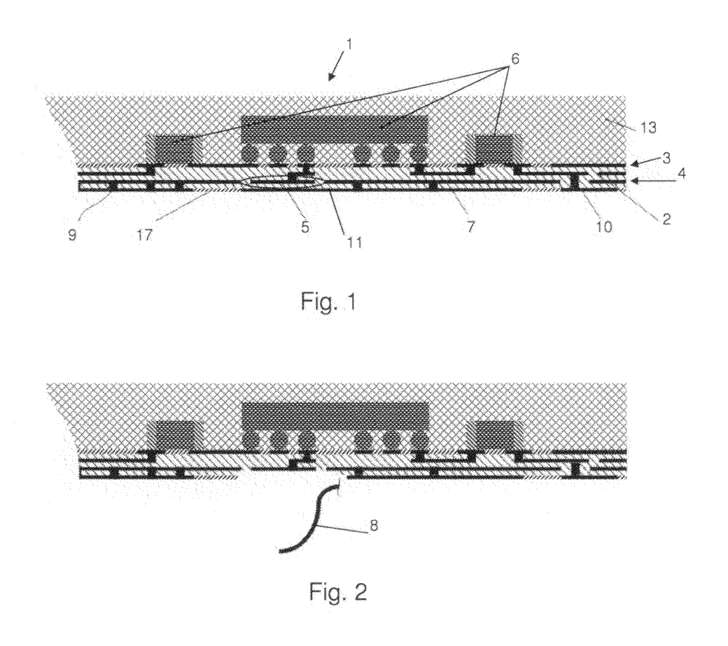

FIG. 1 shows a cross-section of a system in package 1. The shown system in package 1 comprises a substrate 4. On the substrate 4 a first conductive layer 2 is provided which is externally accessible for electrically connecting the system in package 1 to an electric circuit. External contact pads 7 are provided on the first layer 2. The system in package 1 further comprises a second internal conductive layer 3 which is covered by the first conductive layer 2. Electronic devices 6 are provided on the substrate 4 and are electrically connected to the external contact pads 7, 9, 10.

By electrically connecting the system in package 1 to the electric circuit through the first conductive layer 2, the different electronic devices 6 are functionally employed into the electric circuit. By providing predetermined electronic devices 6 which are interconnected internally by the second internal conductive layer 3 and/or the first external conductive layer 2 the system in package 1 can be designed to perform a predetermined electrical functionality by bundling the electrical functionality of the different electronic devices 6. This for example allows providing an electrical functionality into a single package, the system in package 1, such that this functionality can directly be employed into an electric circuit. This way, electrical functionalities can be bundled into relatively small modules and can for example be produced on a relatively large scale.

FIG. 1 for example shows three electronic devices 6 interconnected by the second internal conductive layer 3 such as to perform a predetermined electrical functionality. The predetermined electrical functionality of the electronic devices 6 and the electrical functionality resulting from the interconnection of the second layer 3 are not critical for the invention and can be determined by the person skilled in the art in function of the intended use of the system in package 1. Also the number of the electronic devices 6 is not critical for the invention and can also be determined by the person skilled in the art in function of the desired electrical functionality offered by the system in package 1. For example the system in package 1 may comprise a central processing unit, a memory possibly combined with passive components such as resistors, inductors and capacitors which, when appropriately electrically interconnected, can provide a fully operational computer system in a single package.

Every type of electronic device 6 can be used to form the system in package 1, but often the electronic devices 6 used in the system in package 1 are integrated circuits. Using integrated circuit 6 moreover has the advantage that the volume of the system in package 1 can be reduced.

The first conductive layer 2 is often provided to be attached to a further substrate, for example but not limited thereto a printed circuit board, and thereto is often, as shown in FIG. 1, as flat as possible. This is however not critical for the invention and the first layer can also have another shape depending on the way the system in package 1 will be mounted into its final location.

The electronic devices 6 provided on the substrate 4 are in FIG. 1 more specifically provided on the second internal conductive layer 3. This is however not critical for the invention and at least one of the electronic devices 6 can also be provided on the first conductive layer 2. However, when providing all electronic devices 6 on the second layer 3, the location of the electronic devices 6 interferes less with the provision of the first layer 2. Especially when the system in package 1 is mounted to a further substrate at the first layer 2, it has been found that the electronic devices 6 are better provided on the second layer 3 such that they interfere less with the mounting of the system in package 1 to the further substrate.

FIG. 1 shows that the second layer 3 and the devices 6 provided thereon are covered with an overmould compound 13 for example ceramic material. Although such an overmould compound is not essential for the invention, such an overmould compound provides the system in package 1 with an increased robustness by protecting the second layer 3 and the electronic devices 6.

FIG. 1 shows three external contact pads 7 lying next to each other. However, the location and the number of the external contact pads 7 are not critical for the invention and can be adapted by the person skilled in the art. For example more or less external contact pads 7 can be provided and/or the external contact pads 7 can be provided on different locations.

One of the external contact pads 7 can be provided to be a ground pad 9 and therefore be provided to be electrically connected to a ground signal. However one of the external contact pads 7 can also be provided as a signal pad 10 and therefore be provided to be electrically connected to a signal different from the ground signal. This is however not critical for the invention.

One of the external contact pads 7 can, possibly but not necessarily in addition to being a ground pad 9 or a signal pad 10, be a soldering pad 11. The soldering pad 11 is provided to be soldered to the further substrate, such as for example a printed circuit board and thereto preferably has a predetermined size for dissipating heat caused by soldering the soldering pad 11 to the further substrate.

The substrate 4 shown in FIG. 1 is a land grid array substrate in which the external contact pads 7 are substantially flat and form an array on one of the external surfaces of the system in package 1, more in particular a mounting surface 17 to which the system in package 1 will be mounted to a further substrate. This is however not critical for the invention and the substrate 4 may also be, for example, a pin grid array in which the external contact pads 7 are in the form of pins extending from the mounting surface 17, ball grid array in which the external contact pads 7 are in the form of balls, etc. In addition, also the provision of the external contact pads 7 in the form of an array is not critical for the invention and the external contact pads 7 can also be, for example, randomly distributed on the external surface 17 of the system in package 1.

FIG. 1 also shows a hidden contact pad 5 on the second layer 3. The hidden contact pad 5 is similar to the external contact pads 7 with the differences of being provided on the second layer 3 and being hidden by at least part of the first layer 2 such that it is only accessible after removal of a removable part 8 of the first layer 2.

FIG. 2 shows the cross-section according to FIG. 1 after removal of a removable part 8 of the first layer 2. The removable part 8 shown in FIG. 2 is a part of one of the external contact pads 7, more precisely the ground pad 9, of the first layer 2. This is however not critical for the invention and other parts of the first layer 2, not being an external contact pad 7, can also be the removable part 8. Moreover, also part of a signal pad 10 or a soldering pad 11 not being a signal pad 10 or soldering pad 11 could be the removable part 8. The removable part 8 can even comprise a complete external contact pad 7. When only part of the external contact pad 7 is part of the removable part 8, the remaining part of the external contact pad 7, after removal of the removable part 8, can still be used as, for example, signal pad 10, ground pad 9 and/or soldering pad 11.

The removable part 8 can be removed by, for example, scratching away the removable part 8, pulling away, peeling off the removable part 8, chemically removing the removable part 8, etc. Preferably, the removable part 8 is removed by scratching away the removable part 8, since such a removal can easily be performed without using further equipment and without substantial mechanical provisions to the system in package 1.

The revealed hidden contact pad 5 can have any functionality known to the person skilled in the art. The hidden contact pad 5 can for example be a soldering pad and/or can have an electrical functionality such as for example being a ground pad, a signal pad, etc. as is described for the external contact pad 7.

In case for example the removable part 8 is one of the external contact pads 7, the functionality of the hidden contact pad 8 can be different from the functionality of the removed external contact pad 7. Such that when, for example, the removed external contact pad 7 was a ground pad 9, the hidden contact pad 5 can perform the function of a signal pad or when the removed external contact pad 7 was a signal pad 10, the hidden contact pad 5 can also be a signal pad but for a different electrical signal and/or for a different electrical functionality, etc.

This way it is for example possible to provide different electronic alternatives on a single system in package 1. For example, a system in package 1 can be provided with two alternative electronic devices. The external contact pad 7 can for example be configured such as to direct a first of these electronic devices, whereas the hidden contact pad 5 is provided to direct a second of these electronic devices, alternative to the first electronic device. This way, the system in package 1 by default offers the possibility to use the first electronic device but can be configured to use the second electronic device by removing the external contact pad 7 and instead using the hidden contact pad 5. The first electronic device for example is a WIFI transmitter and the second electronic device for example is an UMTS transmitter.

In a further example, in case the removable part 8 is one of the external contact pads 7 and the external contact pad 7 has a different functionality from the hidden contact pad 5, at least one of the devices 6 is electrically connected to an additional hidden contact pad 5 on the second layer 3 which is only accessible after removal of the removable part 8 of the first layer 2, the additional hidden contact pad 18 can have the same functionality as the external contact pad 7 of the removable part 8. Such a configuration allows that although the whole external contact pad 7 is part of the removable part 8, the functionality of the external contact pad 7 is nevertheless not lost when removing the external contact pad 7. However, the hidden contact pad 18 can also have a different functionality from the external contact pad 7 and as the initial contact pad 5 such as to offer further functionalities to the system in package 1.

Although one additional hidden contact pad 18 can be sufficient, the number of hidden contact pads 18 is not essential for the invention and more than one additional contact pad 18 can be provided such as for example two, three, four, etc.

In a further example it is for example also possible that more than one external contact pads 7 are part of the removable part 8.

It is for example possible that the removable part 8 comprises more than one external contact pad 7 which cover only a single hidden contact pad 18. Such a configuration for example allows that unnecessary contact pads, which are for example often used, can be removed and replaced in specific uses of the system in package 1.

The number of external contact pads 7, as a whole or in part, which are part of the removable part 8, the number of hidden contact pads 5 and/or their functionalities combined and/or individually are not critical for the invention and can be determined by the person skilled in the art depending on the specific envisioned use of the system in package 1.

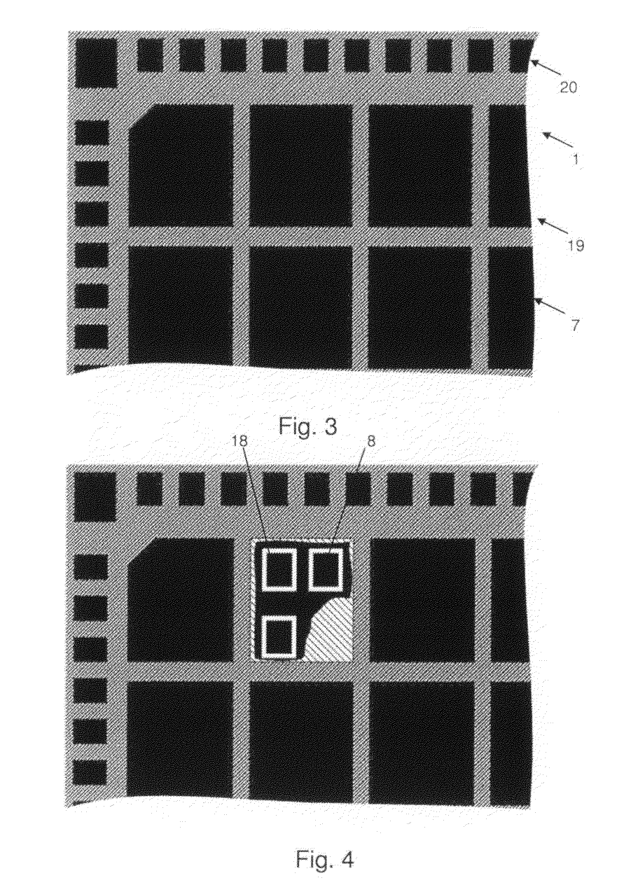

FIG. 3 shows a detail of a bottom view of the system in package 1 and shows eight central external contact pads 19 surrounded by a series of surrounding contact pads 20. The surrounding external contact pads 20 are provided as signal pads and the central external contact pads are provided as ground contact pads and solder contact pads. The configuration of the different contact pads 7 is, as mentioned above, however not critical for the invention and can be altered by the person skilled in the art depending on the envisioned use of the system in package 1.

The system in package 1 in this case is a quad flat package, more precisely a quad flat package no lead. Specifically, the land grid array substrate, as discussed above, is also shown. However, other types of systems in package 1 are nevertheless possible and can be determined by the person skilled in the art.

The upper left external contact pad 7 has part of one of its corners removed for indicating a predetermined orientation of the system in package 1. This allows the system in package 1 to be correctly electrically connected to an electrical circuit. The form and shape of the means which allow the system in package 1 to be oriented, in this case the removed corner, are not critical and any other indication can be used such as for example a mark on the substrate 4, etc.

FIG. 4 differs from FIG. 3 in that one of the external contact pads 7 is broken away revealing three hidden contact pads 5. In case the external contact pad 7 broken away was a soldering pad and was not provided to be a signal pad or ground pad, the soldering functionality in such a case could be taken over by, for example, the adjacent external contact pads 7 or one of the revealed hidden contact pads 5.

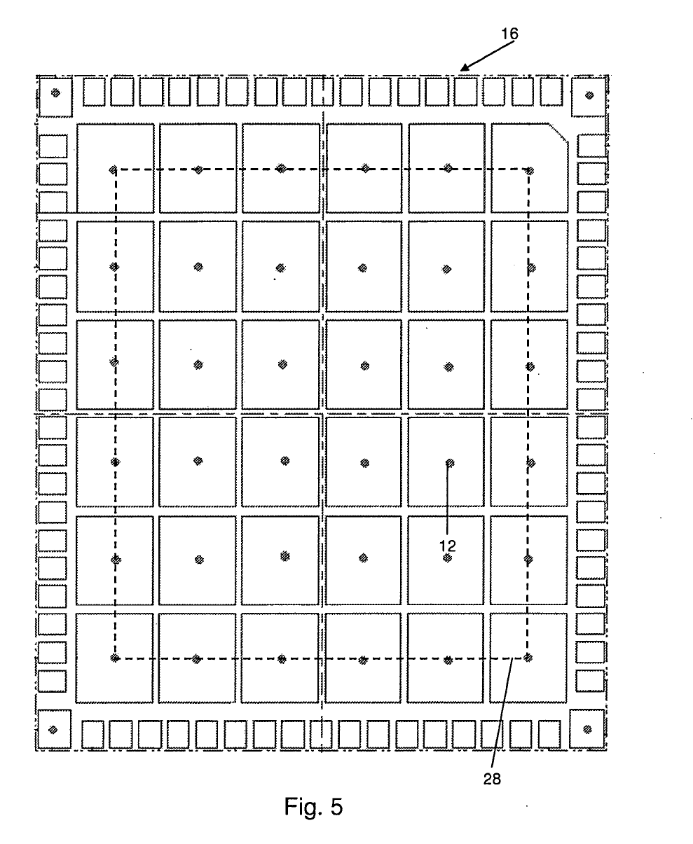

FIG. 5 shows a top view of a printed circuit board 16 with indications for the desired location of electronic devices, such as for example the system in package shown in FIGS. 2 and 3, also known under the name of a land pattern. The printed circuit board 16 comprises a printed circuit board substrate on which an electrical circuit is electrically provided to be electrically connected to the system in package 1. The electrical circuit is however not shown in the figures.

The system in package 1, or any other system in package or in general every electronic device, can be soldered to the printed circuit board substrate by means of at least one soldering pad 11 on the electronic device. The printed circuit board substrate shown in FIG. 5 comprises a single through-hole 12 in the centre of the area of where such a soldering pad 11 will be provided. Such a through-hole 12 allows flux gasses resulting from soldering to escape. Although the through-hole 12 is provided in the centre of the area of where the soldering pad 11 will be provided, the through-hole 12 can also be provided at any other location in the area of where the soldering pad 11 will be provided. Also, although only a single through-hole 12 is provided, more than one through-hole 12 can be provided in the area where the soldering pad 11 will be located.

Although FIG. 5 shows that a through-hole 12 is provided on the location of each of the soldering pads 11, this is not critical for the invention and some through holes 12 may be omitted. However, it has been found by the inventor that a symmetrical location of the through holes on the printed circuit board offers an improved effect of the escape of the gasses resulting from the soldering. For example, with respect to FIG. 5, omitting the through holes 12 at the four corner contact pads 7 and/or only providing through holes 12 at the contact pads 28 delimiting the field of contact pads 7, in the case of FIG. 5, twenty contact pads.

The through holes 12 preferably have a diameter of between 0.5 and 0.9 mm, more preferably between 0.6 and 0.8 mm and most preferably of 0.7 mm. Such diameters have been found to decrease the risk that leakage of soldering material, particularly solder paste, occurs through the through-hole 12.

Preferably, the through holes 12 are non plated which have been found to avoid leakage of soldering material, more in particular soldering paste.

Accordingly a system in package 1, not limited to the system in package 1 described above but in general every electronic device, can be attached to a printed circuit board by soldering a soldering pad 11 of the electronic device onto the printed circuit board substrate such that the system in package 1 is electrically connected to an electrical circuit provided on the printed circuit board substrate. To obtain the desired escape of gasses resulting from the soldering, prior to soldering, one or more of through holes 12, as mentioned above, are provided in the printed circuit board, preferably through the printed circuit board substrate as explained above, in the area where the soldering pad 12 is to be soldered to the printed circuit board 16.

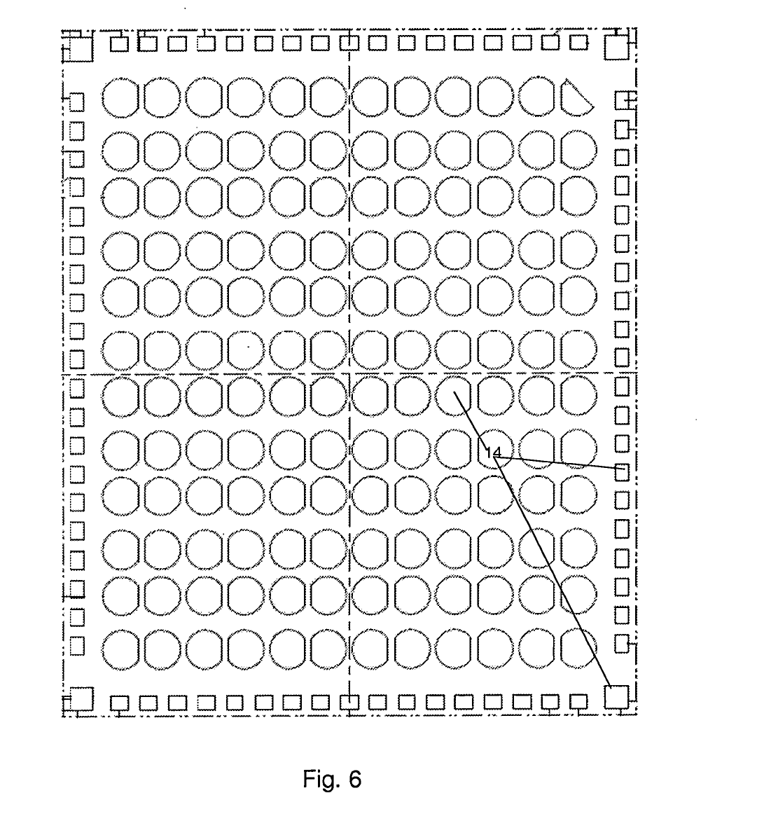

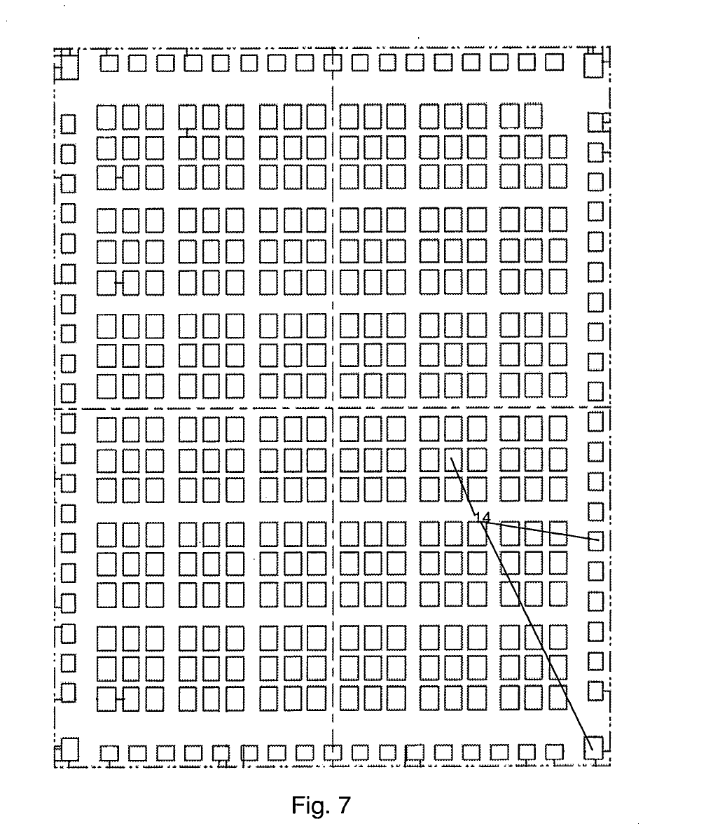

FIG. 6 shows a top view of a pattern 14 for applying soldering material, more specifically solder paste, onto the printed circuit board shown in FIG. 5. More specifically a stencil made on this basis can be used to apply soldering material, more specifically soldering material, to the further substrate, for the example the printed circuit board 16. As can be seen on FIG. 6, care has been taken to avoid application of soldering material onto the through-hole 12. However, a different pattern can be used for applying solder paste onto the printed circuit board 16 such as the pattern for example shown in FIG. 7 which also shows an improved escape of gasses resulting from the soldering.

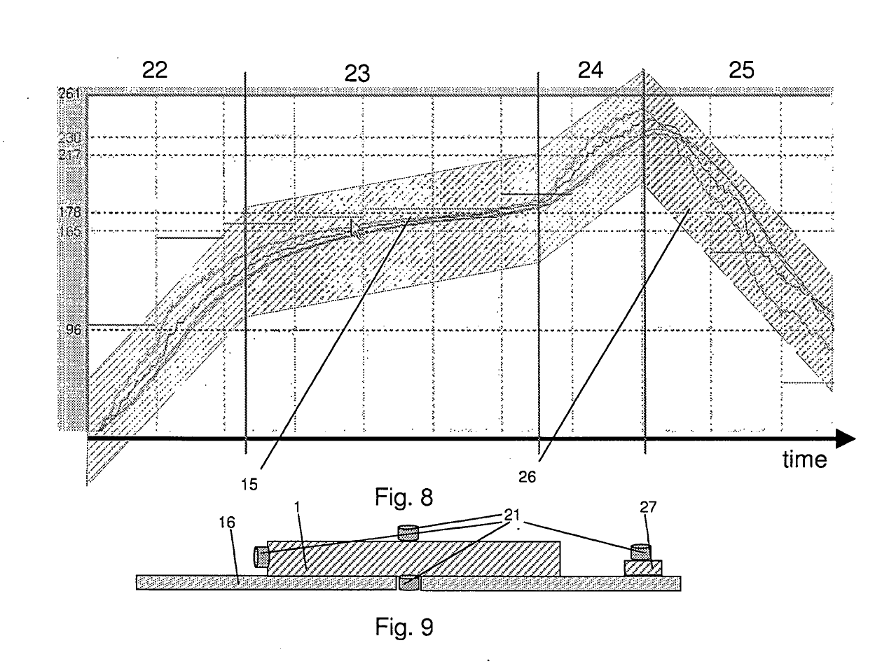

After application of the soldering material to the printed circuit board 16 and after mounting of the system in package 1 to the printed circuit board 16, the soldering material needs to be heated in order to attach the system in package 1 to the printed circuit board 16. This process is usually known to the person skilled in the art as reflow. The reflow process preferably applies subsequent steps of heating or cooling to the assembly of the printed circuit board 16 with the system in package 1. This is for example illustrated in FIG. 8 in which the X-axis indicates the different steps applied, and in other words indicates time, and in which the Y-axis indicates the temperatures to which the assembly of printed circuit board 16 and system in package 1 are subjected. The curve 15 in other words indicates the temperature in function of time to which the assembly of the printed circuit board 16 and system in package 1 is subjected and are often called reflow profiles by the person skilled in the art. The different temperature curves 15 in FIG. 8 correspond to the temperature measurements on various locations of an assembly of a system in package 1 and a surface mounted device 27 mounted on a printed circuit board 16 by thermocouples 21 on predetermined locations as shown in FIG. 9. As known by the person skilled in the art the temperature curves 15 can be divided in four regions 22, 23, 24, 25: a preheat region 22, a soak zone 23, a reflow zone 24 and a cooling down zone 25. The soak zone 23 allows the flux to be activated such that the wetting characteristics of the solder material, preferably solder paste, are improved. In each zone each of the curves should be within a range 26, known by the person skilled in the art as the gabarit, indicated in the FIG. 8. The inventor has found that by keeping the rise of temperature in the soak zone 23 within a range of 7° C./min-15° C./min, more preferably 10° C./min, the escape of flux gasses resulting from the heating of the soldering material dramatically improves. The duration of the soak zone 23 should preferably be long enough to allow substantially all gasses formed by soldering to escape.

The inventor has also found that it is beneficent in order to have a smooth rise in temperature in the soak zone 23 to start the soak zone at the flux activation temperature to get quick flux activation and will result in a better and more complete escape of flux gasses resulting from soldering, before entering the reflow zone 24. Alternatively, as to avoid thermal stress and to have complete escape of flux gasses, one can enter the soak zone at lower temperature and as compensation for example prolong the soak zone.

However the precise reflow profile 15 is not essential for the invention and can be further determined by the person skilled in the art depending on the specific printed circuit board 16 and the system in package 1 used.

1. Method for providing a printed circuit board (16) with an electronic device (1), wherein the electronic device (1) having at least one external soldering pad (11) having a predetermined size for heat dissipation is soldered with the soldering pad (11) onto a printed circuit board substrate of the printed circuit board (16) such that the electronic device (1) is electrically connected to an electrical circuit provided on the printed circuit board substrate, wherein prior to soldering, one or more through holes (12) are provided in the printed circuit board in the area where the soldering pad (12) is to be soldered to the printed circuit board (16) such that the through hole is provided for allowing flux gasses resulting during soldering of the electronic device (1) to the printed circuit board to escape.

2. Method according to claim 1, wherein the rise of temperature within a soak zone (23) during soldering is kept within a range of 7° C./min-15° C./min, more preferably 10° C./min.

3. Method according to claim 1, wherein the through hole (12) has a diameter of between 0.5 and 0.9 mm, more preferably between 0.6 and 0.8 mm and most preferably of 0.7 mm.

4. Method according to claim 1, wherein the through hole is provided through the printed circuit board by providing a through hole only through the printed circuit board substrate aside the electrical circuit.

5. Printed circuit board (16) provided with an electronic device (1) according to claim 1, comprising a printed circuit board substrate on which an electric circuit is provided, the electronic device (1) being electrically connected to the electric circuit, an external soldering pad (11) of the electronic device (1) having a predetermined size for heat dissipation being soldered to the printed circuit board (16), the printed circuit board (16) comprising one or more through holes (12) extending through the printed circuit board (16), wherein the through hole (12) is provided for allowing flux gasses resulting during soldering of the electronic device (1) to the printed circuit board to escape.

6. Printed circuit board (16) according to claim 5, wherein the soldering connecting the soldering pad (11) of the electronic device (1) covers the through hole (12).

7. Printed circuit board (16) according to claim 5, wherein the through-hole (12) is provided at the centre of the soldering pad (11).
